(19) United States
(12) Patent Application Publication
(10) Pub. No.: US 2004/0135265 A1
(43) Pub. Date: Jul. 15, 2004

(54) Contacting microchips by means of pressure

(76) Inventors: Elke Zakel, Falkensee (DE); Thorsten Teutsch, Berlin (DE)

Correspondence Address: ANTHONY J VALLELUNGA, 209 SCHOOLHOUSE ROAD, ALBANY, NY, 122035956

(21) Appl. No.: 10/468,054

(22) PCT Filed: Feb. 13, 2002
(86) PCT No.: PCT/EP02/01511

(30) Foreign Application Priority Data
Feb. 13, 2001 (DE) 101 06 488.8
Apr. 24, 2001 (DE) 101 20 029.3

(51) Int. Cl. H01L 21/44; H01L 23/48

(52) U.S. Cl. 257/782; 438/118; 257/783

(57) ABSTRACT

A method for contacting microchips is provided, in which an adhesive is deposited such on a side of a substrate, on which a conductor trace is located, and/or on a side of a microchip, on which at least one bump is located, such that a liquid layer of adhesive is formed on the same. Subsequent to adjusting the microchips such that the at least one bump is located above a predetermined site on the conductor trace of the substrate, a press contact between the at least one bump and the predetermined site is produced by exerting a pressure between the microchip and the substrate, with the adhesive being subsequently cured.

The present invention relates to the field of contacting of microchips.

By means of progressive developments it is nowadays possible to manufacture microchips with a very high packing density. In order to keep abreast with this development, suitable contacting methods are required, so as to be able to securely connect the growing number of electrical terminals on microchips to intended areas of a substrate.

A prior art method represents the wiring method, in which the terminals are connected by means of thin metal wires. A disadvantage of this method consists in that a separate mechanical and electrical connection is required. Further, the wires make up an additional inductive component, affecting a switching speed of the circuit.

A further prior art method for contacting and mounting microchips is the TAB method (TAB=tape automated bonding). With this method, the front side of the die is applied on an intermediate carrier, for example a plastic tape made of polyamide. Simultaneously electrical terminals on the die serve as a mechanical mount, with bumps being typically used so as to produce the mechanical and electrical connection to a conductive pattern on the tape. Bumps are small elevations which may take on varying metallic compositions and shapes and which are mounted to the contact pads of the microchips and/or the contacting areas of the conductive pattern. The process of being mounted to the actual substrate is subsequently effected by a punching of the tape and a further soldering process for the external terminals.

A third prior art method represents the flip-chip method, in which a front side of a microchip is being directly mounted to a substrate. As in the case of the TAB method, bumps are used in this method, so as to produce the mechanical and electrical connections of the pads of the microchip to the contacting areas of a conductive pattern on the substrate, with the option of using a soldering or thermal compression process being provided.

Further, die-contacting methods may also be carried out without using any bumps. The U.S. Pat. No. 6,107,118, for example, describes a method, in which the connection sections of a substrate and contact areas of a die abut each other and are being mounted by a non-conductive adhesive. In this process, the adhesive is applied to a first surface of a substrate comprising the conductive connection sections. By applying a predetermined temperature and a predetermined pressure, the non-conductive adhesive layer becomes activated such that an electrical contact of the contact areas of the die to the connection sections of the substrate is produced without using any metallic bonding method, such as for example soldering.

It is the object of the present invention to provide a method which makes it possible to advantageously contact a microchip.

This objective is achieved by a method in accordance with claim 1.

The present invention provides a method for contacting microchips, comprising the following steps:

providing a substrate with a conductor trace being arranged on one side of the substrate;

applying of at least one bump on one side of a microchip;

depositing an adhesive on the side of the substrate on which the conductive trace is located and/or on the side of the microchip on which the at least one bump is located such that a layer of the adhesive is formed on the same;

adjusting the microchip such that the at least one bump is located above a predetermined site on the conductor trace of the substrate;

manufacturing a press contact between the at least one bump and the predetermined site by exerting a pressure between the microchip and the substrate; and

curing of the adhesive.

In a preferred embodiment a microchip is connected to a substrate by means of bumps which are applied on contacting areas on a front side of the same. In the process, a glue is applied on one side of the substrate, which comprises a conductive pattern, such that a liquid adhesive layer is formed. The microchip and the substrate are subsequently adjusted such that the bumps are each located over predetermined sites of the conductor trace. Thereupon, a press contact between the bumps and the respective predetermined sites is made by exerting a pressure between the microchip and the substrate, while, depending on the hardness degree of the materials being used for the bumps and the conductor trace of the substrate, a plastic deformation of the bumps, a plastic deformation of the conductor trace at the predetermined site or a plastic deformation of the bumps and of the conductor trace at the predetermined site may result. Subsequently, the glue is cured, as a result of which the cured glue maintains the generated contacts in an upright position.

Further developments of the present invention are set forth in the appended claims.

Preferred embodiments will be explained in detail below with reference to the attached drawings, in which:

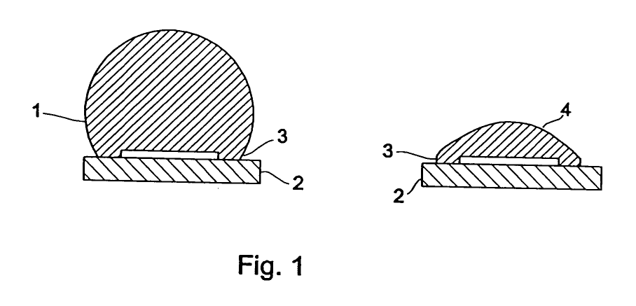

FIG. 1 shows two bump types, which may be used in a press contacting;

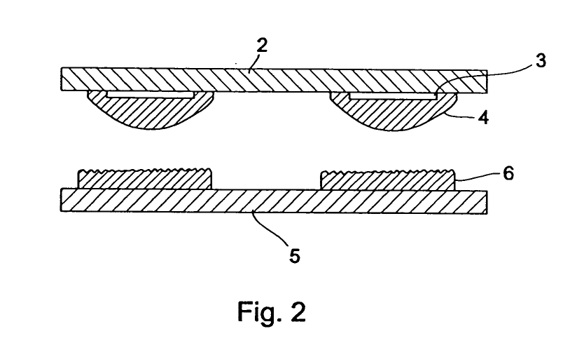

FIG. 2 shows a schematic illustration of a microchip and a substrate prior to a press contacting;

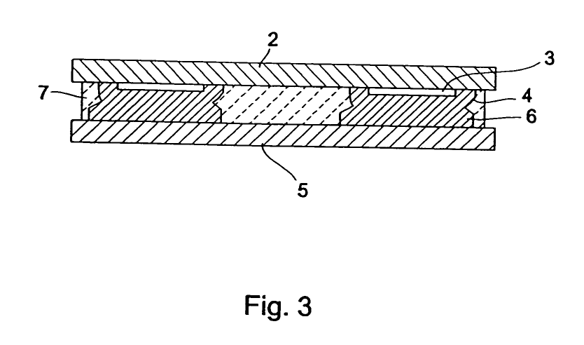

FIG. 3 shows a schematic illustration of the microchip and substrate from FIG. 2 after a press contacting, during which a bump is being plastically deformed; and

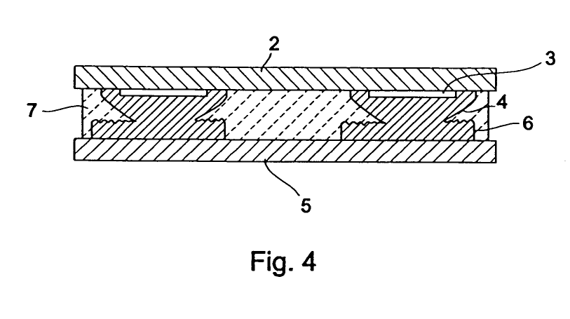

FIG. 4 shows a schematic illustration of the microchip and of the substrate from FIG. 2 after a press contacting, during which a conductor trace is being plastically deformed.

FIG. 1 shows two bump types, which may be used in a press contacting of microchips in accordance with the present invention. As a first type, a solder ball is shown in FIG. 1, which is applied to a die 2 which comprises a UB metallization 3 (UB=under bump) on its active side. The form of the solder surface represents an essential characteristic of the bumps. While the solder ball 1 comprises a round shape, a solder meniscus 4 which is shown in FIG. 1 as a second example of a bump, comprises a flat, dome-like solder surface profile.

With respect to any desired physical and chemical properties, solder materials for bumps may comprise different alloys for an application. For example, an alloy of PbSn 37/63 represents a soft solder material, while an alloy of AuSn 80/20 corresponds to a hard solder material. Beside the hardness of the material, further material properties which are important in practice include a melting temperature, an electrical conductivity and a mechanical adhesion anchorage.

FIG. 2 shows a microchip 2, which offers contacting areas on its active side in the form of two bumps 4 in the form of solder menisci. The active side of the microchip 2, to which the bumps 4 are applied, faces a side of a substrate 5, to which two conductor traces 6 are applied. The conductor traces 6 of the substrate 5 may consist of different materials. Typically, materials, such as e.g. Ag, Ag/Pd, Cu, Ni/Au, Al, Cu/Ni/Au are used. A common method for producing the conductor traces 6 represents a gluing technique, in which an adhesive, such as, for example, a silver-conducting adhesive, carbon or the like, is used so as to fix the conductor traces on the substrate 5. Further, the conductor traces 6 may be formed by a conventional thick film method.

In accordance with a preferred embodiment, an electrically non-conductive glue or any other suitable adhesive is deposited on the side of the substrate 5 comprising the conductor trace 6. The deposition of the non-conductive electrical glue is effected for example by means of a dispense method or a print method.

In the dispense method, a drop mist of the glue is generated, for example, by a needle or a capillary. The droplets deposit on the adhesive surface so as to form a liquid layer of the glue.

In the print method, the glue is deposited directly onto the substrate and/or the microchip 2 using prior art print methods, with a liquid layer of the glue being used.

After depositing the glue, the side on which the glue was deposited, comprises a liquid layer of the glue. The microchip 2 is subsequently orientated with respect to the substrate 5 by means of a suitable adjusting device such that the bumps 4 are each located over predetermined sites on the conductor trace 6 of the substrate 5, at which the electrical contact with the bump 4 is to take place. After adjusting, the microchip 2 and the substrate 5 are approximated such that the bumps 4 contacts the intended sites on the conductor trace 6. Depending on the material properties of the solder material and of the conductor trace 6 of the substrate 5, the pressure exerted in the process causes the bump 4 and/or the intended site on the conductor trace 6 of the substrate 5 to deform and to adjust.

In the process, a hard solder material, such as, for example, AgSn 80/20, with a soft conductor trace material causes the bumps 4 to penetrate the conductor trace, as a result of which the surface of the conductor trace 6 deforms locally at the predetermined sites and adjusts to the surface of the bump.

Conversely, a soft soldering material, such as, for example PbSn 37/63, with a hard conductor trace material causes the solder surface to be deformed and to adjust to the patterns of the conductor trace 6.

Further, given an approximately equal hardness of the solder material and the conductor trace material, a plastic deformation of both the solder material and the conductor trace material may take place at the predetermined site and as a consequence a mutual adaptation.

By way of the plastic deformation, a micro-roughness adaptation of the interfaces takes place, which, on the one hand, guarantees good mechanical anchorage of the bumps 4 and, on the other hand, a good electrical conduction.

The heat generated in the print process further supports the deformation and adaptation process of the solder material and/or of the conductor trace material, as a result of which micro-roughness adaptation is still improved. The metallic solid body contact manufactured in this way forms an electrical connection between the bump 4 and the predetermined site on the conductor trace 6 of the substrate 5.

Subsequent to press contacting, the glue is cured so as to maintain the contact. The contact is primarily of a physical nature, with local chemical compound shares also being possible. The curing of the glue takes place by supplying heat. The heat may, for example, be generated by a thermode (i.e. a pin with a resistance heat wire), which is pressed onto the rear side of the die, or a laser beam, which is coupled to the die, or by any other suitable method generating heat without destroying the microchip 2.

For underlining the previously mentioned options of a plastic deformation, an example of a plastic deformation of a bump 4 is shown in FIG. 3 and an example of a primarily plastic deformation of a conductor trace 6 is shown in FIG. 4.

FIG. 3 shows an example of a press contacting, in which the bumps 4 on the microchip comprise a soft solder material, such as for example PbSn 37/63, while the conductor traces 6 of the substrate 5 are formed with a hard material. The arrangement shown in FIG. 3 corresponds to the arrangement prior to a press contacting from FIG. 2.

As can be seen, the bumps 4 comprising a soft material deform such that the same, after a press contacting, comprise a different solder shape than prior to the contacting. The plastic deformation of the bumps 4 causes the dome-shaped solder surface of the bumps 4 to become depressed by the pressure contact with the surface of the conductor traces 6, with the same adjusting to the surface of the conductor traces 6. Especially it may be recognized that the soft solder material spatially fills the micro-roughness of the conductor trace surface, such that, along the conductor surface, there are essentially no spatial gaps. These micro-roughness adaptation results in a good mechanical and electrical connection of the bumps 4 to the conductor traces 6.

The resulting connection between the bumps 4 and the conductor traces 6 is further embedded into the non-conducting glue 7, as a result of which the glue 7, after having cured, maintains the connection between the microchip 2 and the substrate 5. Further, the cured glue 7 provides an electrical insulation and a mechanical protection for the connection.

In FIG. 4, an example of a pressed contacting with a hard solder material shows the bumps 4 and a soft conductor trace material of the conductor traces 6. The arrangement illustrated in FIG. 4 illustrates, as in the example from FIG. 3, an arrangement corresponding to an arrangement shown in FIG. 2 prior to contacting.

In accordance with FIG. 4, it is primarily the conductor trace 6 in the contacting area, which in this case experiences a plastic deformation. As a result, the bumps 4 essentially maintain their original shape and, with their copular-shaped surface in a connection area of the conductor trace 6, penetrate the deforming conductor trace 6, which essentially adjusts to the shape of the bumps 4. As can be seen, the micro-roughnesses adjust to the surface of the conductor traces 6 in the area of a contact of the surface of the bumps 4, so that, after press contacting, there are essentially no spatial gaps at the contact surface.

Corresponding to the example shown in FIG. 3, the glue 7 in turn encloses the space between the microchip 2 and the substrate 4, embedding the resulting contact connection. Also in this case, after curing, the glue 7 further maintains the connection and represents an electrical insulation and mechanical protection.

While a preferred embodiment has been described such that a glue 7 was deposited only on one side of the substrate, in different embodiments the glue 7 may be deposited on the side of the microchip 2, or the glue may be deposited both on a side of the substrate and on a side of the microchip 2.

Although, in the preferred embodiment, use is made of a glue 7 forming a liquid layer, which cures, other adhesives may also be considered. Especially, adhesives, tapes and laminates, which are paste-like and may be cured by means of heat.

Curing generally takes place by suitable curing methods, such as, for example, the heat treatment of the adhesive. For this purpose, supply of heat by a thermode, laser treatment or a furnace are considered.

1. Method for contacting of microchips, comprising the following steps:
providing a substrate (5) having a conductor trace (6) which is arranged on a side of the substrate (5);
applying at least one bump (1; 4) on a side of the microchip (2);
depositing an adhesive (7) on the side of the substrate, on which the conductor trace (6) is located, and/or on the side of the microchip (2), on which the at least one bump (1; 4) is located, such that a layer of adhesive (7) is formed on the same;
adjusting the microchip (2), such that the at least one bump (1; 4) is located over a predetermined site of the conductor trace (6) of the substrate (5);
producing a press contact between the at least one bump (1; 4) and the predetermined site by exerting a pressure between the microchip (2) and the substrate (5); and
curing of the adhesive (7).

2. Method in accordance with claim 1, in which the step of providing a substrate (5) includes providing a substrate (5) with a metallic conductor trace (6).

3. Method in accordance with claim 1 or 2, in which the step of depositing an adhesive (7) includes depositing the adhesive by means of a dispense method (7).

4. Method in accordance with claim 1 or 2, in which the step of depositing an adhesive (7) includes depositing the adhesive (7) onto the substrate (5) by means of printing.

5. Method in accordance with one of the preceding claims, in which the step of curing the adhesive (7) includes curing by means of heat treatment.

6. Method in accordance with one of claims 1 to 4, in which the step of curing the adhesive (7) includes curing by means of laser treatment or by heat supply by means of a thermode or a furnace.

7. Method in accordance with one of the preceding claims, in which the at least one bump (1) is a solder ball.

8. Method in accordance with one of claims 1 to 6, in which the at least one bump (4) is a solder meniscus.

9. Method in accordance with one of the preceding claims, in which the adhesive (7) is an electrically insulating adhesive.

10. Method in accordance with one of the preceding claims, in which the step of producing a press contact comprises a plastic deformation of the at least one bump (1; 4).

11. Method in accordance with one of claims 1 to 9, in which the step of producing a press contact comprises a plastic deformation of the conductor trace (6) at the predetermined site.

12. Method in accordance with one of claims 1 to 9, in which the step of producing a press contact comprises a plastic deformation of the at least one bump (1; 4) and the conductor trace (6) at the predetermined site.
